(19) United States
(12) Patent Application Publication
(10) Pub. No.: US 2025/0357899 A1
(43) Pub. Date: Nov. 20, 2025

(54) HIGH FREQUENCY POWER AMPLIFIER

(71) Applicant: Murata Manufacturing Co., Ltd., Nagaokakyo-shi (JP)

(72) Inventor: Kiichiro TAKENAKA, Nagaokakyo-shi (JP)

(21) Appl. No.: 19/208,649

(22) Filed: May 15, 2025

(30) Foreign Application Priority Data
May 15, 2024 (JP) 2024-079551

(51) Int. Cl. H03F 1/02; H03F 1/56; H03F 3/24; H03F 3/60

(52) U.S. Cl. CPC H03F 1/0288; H03F 1/56; H03F 3/245; H03F 3/602; H03F 2200/198; H03F 2200/451

(57) ABSTRACT

A hybrid coupler includes a first port, a second port, a third port, and a fourth port. An input signal splitter splits a first input signal at a high frequency into two second input signals. A peak amplifier includes two first amplifiers. The two first amplifiers amplify two high frequency signals obtained by splitting a first one of the second input signals, and output ends of the two first amplifiers are coupled to the first port and the second port. A carrier amplifier includes two second amplifiers and a combiner. The two second amplifiers amplify two high frequency signals obtained by splitting a second one of the second input signals. The combiner combines the high frequency signals amplified by the two second amplifiers together and inputs a combined high frequency signal to the third port.

### CROSS REFERENCE TO RELATED APPLICATION

This application claims priority from Japanese Patent Application No. 2024-079551, filed on May 15, 2024. The content of these applications are incorporated herein by reference in its entirety.

### BACKGROUND OF THE DISCLOSURE

### 1. Field of the Disclosure

The present disclosure relates to a high frequency power amplifier.

### 2. Description of the Related Art

High frequency power amplifiers used for transmitters in wireless communication are circuits that consume the most electric power in wireless communication circuits. In order to suppress power consumption in the wireless communication circuits, techniques for increasing power-added efficiency of the high frequency power amplifiers have been demanded. As a technique for increasing power-added efficiency, load-modulated balanced amplifiers (LMBAs) have been suggested. An LMBA includes a balanced amplifier, a control amplifier, and a hybrid coupler and modulates, by output from the control amplifier, load impedance of the balanced amplifier.

A sequential LMBA has been suggested as an example of LMBAs (see J. Pang, “Analysis and Design of Highly Efficient Wideband RF-Input Sequential Load Modulated Balanced Power Amplifier”, IEEE Trans. on Microwave Theory and Techn., Vol. 68, No. 5, pp. 1741-1753 May 2020). In the sequential LMBA disclosed by Pang (2020), a balanced amplifier operates as a class-C biased amplifier and a control amplifier operates as a class-B biased amplifier. The balanced amplifier and the control amplifier are referred to as a peak amplifier and a carrier amplifier, respectively, by Pang (2020).

### BRIEF SUMMARY OF THE DISCLOSURE

With an ideal hybrid coupler, the level of a high frequency signal traveling from a peak amplifier, passing through the hybrid coupler, and leaking to an output node of a carrier amplifier is negligible, and load impedance of the carrier amplifier does not vary. However, with a real hybrid coupler, leakage of a high frequency signal from a peak amplifier through the hybrid coupler to an output node of a carrier amplifier may occur, and this leakage causes load impedance of the carrier amplifier to vary complexly.

With a peak amplifier biased in class C, as illustrated in FIG. 3C, a load impedance Z_{BA} decreases rapidly with respect to an increase of the level of an input signal. If there is a leakage of a high frequency signal from the peak amplifier to an output node of a carrier amplifier, the load impedance of the carrier amplifier varies depending on frequency around the time when output power of the carrier amplifier reaches a saturation level. Since such variations depend on frequency, it is difficult to attain excellent frequency characteristics.

It is a possible benefit of the present disclosure to provide a high frequency power amplifier having a configuration of a sequential LMBA and capable of achieving wideband characteristics.

According to an aspect of the present disclosure, there is provided a high frequency power amplifier including a hybrid coupler including a first port, a second port, a third port, and a fourth port; an input signal splitter that splits a first input signal at a high frequency into two second input signals; a peak amplifier including two first amplifiers that amplify two high frequency signals obtained by splitting a first one of the second input signals, output ends of the two first amplifiers being coupled to the first port and the second port; and a carrier amplifier including two second amplifiers that amplify two high frequency signals obtained by splitting a second one of the second input signals and a combiner that combines the high frequency signals amplified by the two second amplifiers together and inputs a combined high frequency signal to the third port. A voltage level of the first input signal at a time when an output current of the peak amplifier rises is higher than a voltage level of the first input signal at a time when an output current of the carrier amplifier rises. The hybrid coupler has a configuration in which the high frequency signals inputted to the first port and the second port are combined together and outputted from the fourth port and load impedances of the two first amplifiers of the peak amplifier vary according to a current level of the high frequency signal inputted to the third port from the carrier amplifier.

Since the carrier amplifier includes the two second amplifiers and high frequency signals amplified by the two second amplifiers are combined together and inputted to the hybrid coupler, the carrier amplifier is less likely to be affected by leakage of an output signal from the peak amplifier. Thus, wideband characteristics can be achieved.

### BRIEF DESCRIPTION OF THE SEVERAL VIEWS OF THE DRAWINGS

FIG. 1 is a block diagram of a high frequency power amplifier according to a first embodiment;

FIG. 2 is a schematic equivalent circuit diagram for explaining an operation of a hybrid coupler 30;

FIG. 3A is a graph indicating relationships between an input voltage and output currents of a peak amplifier 10 and a carrier amplifier 20;

FIG. 3B is a graph indicating relationships between an input voltage and output voltages of the peak amplifier 10 and the carrier amplifier 20;

FIG. 3C is a graph indicating relationships between an input voltage and resistance components of load impedances of the peak amplifier 10 and the carrier amplifier 20;

FIG. 3D is a graph indicating a relationship between an input power and a power-added efficiency;

FIG. 4 is a schematic plan view of the hybrid coupler 30 used in a high frequency power amplifier according to a modification of the first embodiment;

FIG. 5 is a schematic perspective view of the hybrid coupler 30 used in a high frequency power amplifier according to another modification of the first embodiment;

FIG. 6 is an equivalent circuit diagram of the hybrid coupler 30 used in a high frequency power amplifier according to still another modification of the first embodiment;

FIG. 7 is a block diagram of a high frequency power amplifier according to a second embodiment;

FIG. 8 is a block diagram illustrating a bias control state at the time when a bias controller 60 performs bias control in a very low power mode;

FIG. 9 is a block diagram illustrating a bias control state at the time when the bias controller 60 performs bias control in a first low power mode;

FIG. 10 is a block diagram illustrating a bias control state at the time when the bias controller 60 performs bias control in a second low power mode;

FIG. 11 is a schematic diagram illustrating a positional relationship between two first amplifiers 12A and 12B of the peak amplifier 10, two second amplifiers 22A and 22B of the carrier amplifier 20, and a drive-stage amplifier 50 in a high frequency power amplifier according to a third embodiment;

FIG. 12 is a schematic diagram illustrating a positional relationship between the two first amplifiers 12A and 12B of the peak amplifier 10, the two second amplifiers 22A and 22B of the carrier amplifier 20, and the drive-stage amplifier 50 in a high frequency power amplifier according to a comparative example;

FIG. 13 is a schematic diagram illustrating a positional relationship between the two first amplifiers 12A and 12B of the peak amplifier 10, the two second amplifiers 22A and 22B of the carrier amplifier 20, and the drive-stage amplifier 50 in a high frequency power amplifier according to a modification of the third embodiment; and

FIG. 14 is a block diagram of a communication apparatus according to a fourth embodiment.

### DETAILED DESCRIPTION OF THE DISCLOSURE

### First Embodiment

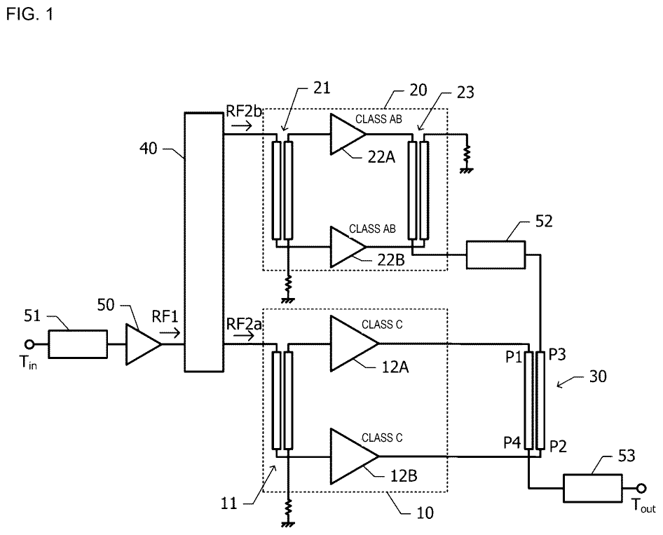

A high frequency power amplifier according to a first embodiment will be described with reference to FIGS. 1 to 3D.

FIG. 1 is a block diagram of a high frequency power amplifier according to a first embodiment. The high frequency power amplifier according to the first embodiment includes a peak amplifier 10, a carrier amplifier 20, a hybrid coupler 30, and an input signal splitter 40. The high frequency power amplifier according to the first embodiment and a peripheral circuit thereof will be described below.

A high frequency signal inputted from an input terminal Tin passes through an impedance matching circuit 51 and is inputted to a drive-stage amplifier 50. The high frequency signal is a signal in a radio frequency band that is modulated in a predetermined communication method. The drive-stage amplifier 50 amplifies the input high frequency signal and outputs a first input signal RF1. The first input signal RF1 amplified by the drive-stage amplifier 50 is inputted to the input signal splitter 40.

The input signal splitter 40 splits the first input signal RF1 into two second input signals RF2a and RF2b and outputs the two second input signals RF2a and RF2b. As the input signal splitter 40, for example, a 3 dB coupler, a Wilkinson splitter, or the like using a coupled transmission line may be used. For example, the signal levels of the second input signals RF2a and RF2b are lower than the signal level of the first input signal by 3 dB and the second input signals RF2a and RF2b have a phase difference of 90 degrees. The second input signal RF2a is inputted to the peak amplifier 10, and the second input signal RF2b is inputted to the carrier amplifier 20. The phase difference between the two second input signals RF2a and RF2b is not necessarily 90 degrees.

The peak amplifier 10 includes two first amplifiers 12A and 12B that amplify two high frequency signals obtained by splitting the second input signal RF2a. The first amplifiers 12A and 12B are, for example, heterojunction bipolar transistors (HBTs). For example, a first splitter 11 splits the second input signal RF2a into two high frequency signals. The signal levels of the two high frequency signals are the same and have a phase difference of 90 degrees. As the first splitter 11, for example, a 3 dB coupler using a coupled transmission line may be used. Each of the first amplifiers 12A and 12B is biased in class C.

The carrier amplifier 20 includes two second amplifiers 22A and 22B that amplify two high frequency signals obtained by splitting the second input signal RF2b. The second amplifiers 22A and 22B are, for example, heterojunction bipolar transistors (HBTs). For example, a second splitter 21 splits the second input signal RF2b into two high frequency signals. The signal levels of the two high frequency signals are the same and have a phase difference of 90 degrees. As the second splitter 21, for example, a 3 dB coupler using a coupled transmission line may be used. Each of the second amplifiers 22A and 22B is biased in class AB. Each of the second amplifiers 22A and 22B may be biased in class B.

The carrier amplifier 20 combines the two high frequency signals amplified by the two second amplifiers 22A and 22B and outputs a combined high frequency signal. For example, a combiner 23 combines the two high frequency signals amplified by the two second amplifiers 22A and 22B together. As the combiner 23, for example, a 3 dB coupler using a coupled transmission line may be used.

The hybrid coupler 30 includes a main line and a sub-line that are electromagnetically coupled to each other. One end of the main line is defined as a first port P1, and the other end of the main line is defined as a fourth port P4. An end portion of the sub-line that is near the first port P1 is defined as a third port P3, and an end portion of the sub-line that is near the fourth port P4 is defined as a second port P2.

Output ends of the two first amplifiers 12A and 12B are coupled to the first port P1 and the second port P2 of the hybrid coupler 30, respectively. An output end of the carrier amplifier 20, that is, an output end of the combiner 23, is coupled to the third port of the hybrid coupler 30 with an impedance matching circuit 52 interposed therebetween. The fourth port P4 of the hybrid coupler 30 is connected to an output terminal Tout with an impedance matching circuit 53 interposed therebetween.

High frequency signals inputted to the first port P1 and the second port P2 are combined together and outputted from the fourth port P4. A high frequency signal inputted to the third port P3 is outputted from the fourth port P4. That is, a high frequency signal with a power that is equal to the total power of high frequency signals inputted to the first port P1, the second port P2, and the third port P3 is outputted from the fourth port P4. Load impedances of the two first amplifiers 12A and 12B of the peak amplifier 10 vary according to the current level of a high frequency signal inputted to the third port P3 from the carrier amplifier 20. More particularly, the load impedances of the two first amplifiers 12A and 12B of the peak amplifier 10 vary according to the ratio of the current level of a high frequency signal inputted to the third port P3 from the carrier amplifier 20 and the current levels of high frequency signals inputted to the first port P1 and the second port P2 from the peak amplifier 10.

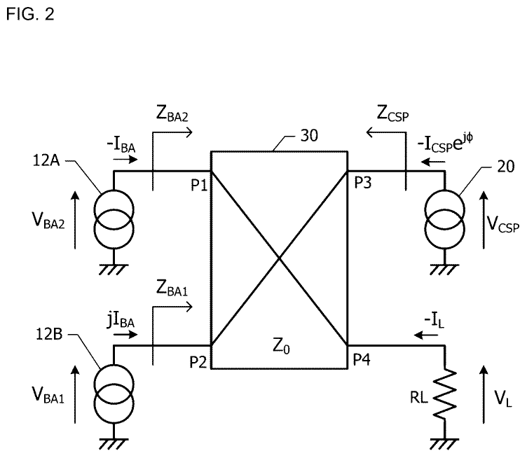

Next, an operation of the hybrid coupler 30 will be described in more detail with reference to FIG. 2. FIG. 2 is a schematic equivalent circuit diagram for explaining an operation of the hybrid coupler 30. The two first amplifiers 12A and 12B of the peak amplifier 10 are regarded as current sources that generate currents −I_{BA} and jI_{BA}, respectively. The carrier amplifier 20 is regarded as a current source that generates a current −I_{CSP}e^{jφ} at a point flowing into the third port P3, where j represents an imaginary unit and φ represents a phase offset. The current −I_{CSP}e^{jφ} represents a current after being outputted from the carrier amplifier 20 and passing through the impedance matching circuit 52.

A load RL is connected to the fourth port P4. A current flowing from the load RL into the fourth port P4 is denoted by −I_{L}. Voltages generated at the first port P1, the second port P2, the third port P3, and the fourth port P4 are denoted by V_{BA2}, V_{BA1}, V_{CSP}, and V_{L}, respectively. Load impedances of the current sources representing the first amplifiers 12A and 12B and the carrier amplifier 20 are denoted by Z_{BA2}, Z_{BA1}, and Z_{CSP}, respectively.

Output currents and output voltages of the individual current sources are expressed by an equation below using an impedance matrix of the hybrid coupler 30, where Z₀ represents a characteristic impedance of the hybrid coupler 30:

$$( \begin{matrix}{V}_{L} \\ {V}_{BA 1} \\ {V}_{CSP} \\ {V}_{BA 2}\end{matrix} ) = {Z}_{0} ( \begin{matrix}0 & 0 & - j & - j \sqrt{2} \\ 0 & 0 & - j \sqrt{2} & - j \\ - j & - j \sqrt{2} & 0 & 0 \\ - j \sqrt{2} & - j & 0 & 0\end{matrix} ) ( \begin{matrix}- {I}_{L} \\ {jI}_{BA} \\ - {I}_{CSP} {e}^{j ϕ} \\ - {I}_{BA}\end{matrix} ) \qquad ( 1 )$$

By expanding Equation (1), the load impedances Z_{BA1} and Z_{BA2} of the two first amplifiers 12A of the peak amplifier 10 (FIG. 1) are expressed by an equation:

$${Z}_{BA 1} = {Z}_{B A 2} = {Z}_{0} ( 1 + \sqrt{2} \frac{{I}_{C S P}}{{I}_{B A}} {e}^{j ϕ} ) \qquad ( 2 )$$

The load impedance Z_{CSP} of the carrier amplifier 20 is expressed by an equation:

$${Z}_{C S P} = {Z}_{0} \qquad ( 3 )$$

As is clear from Equation (2), the load impedances Z_{BA1} and Z_{BA2} of the two first amplifiers 12A and 12B of the peak amplifier 10 are the same and are controlled based on the output current I_{CSP} from the carrier amplifier 20 and the phase offset φ. In contrast, the load impedance Z_{CSP} of the carrier amplifier 20 is constant.

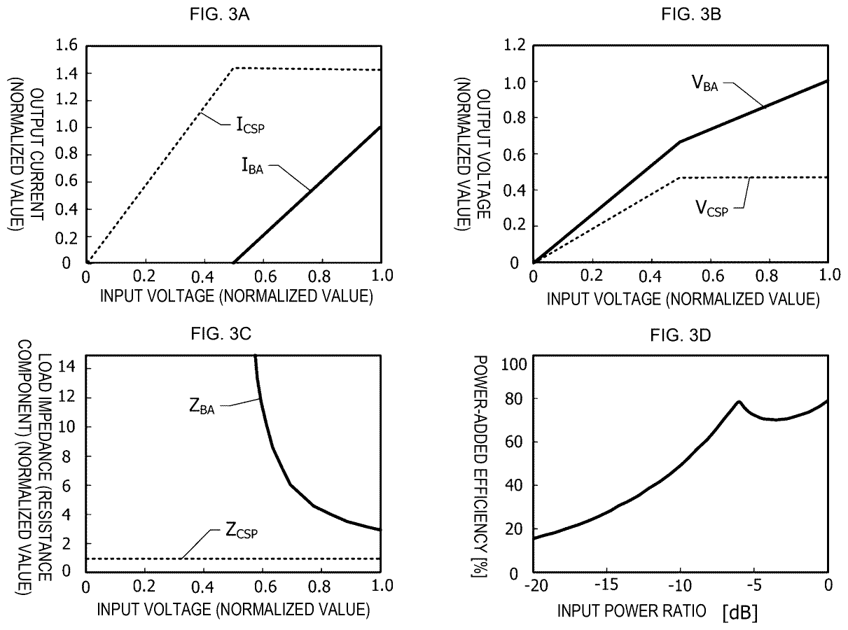

FIG. 3A is a graph indicating relationships between an input voltage and output currents of the peak amplifier 10 and the carrier amplifier 20. The horizontal axis represents an input voltage as a normalized value, and the vertical axis represents an output current as a normalized value. The normalized value of the maximum value of the input voltage is defined as 1 and the normalized value of the maximum value of the output current I_{BA} of the peak amplifier 10 is defined as 1. In the graph indicated in FIG. 3A, a solid line represents the output current I_{BA} Of each of the first amplifiers 12A and 12B of the peak amplifier 10 (FIG. 1), and a broken line represents the output current I_{CSP} of the carrier amplifier 20. Hereinafter, the normalized value of an input voltage may be simply referred to as an “input voltage”, and the normalized value of an output current may be simply referred to as an “output current”.

The voltage level of the second input signal RF2a at the time when the output current I_{BA} of the peak amplifier 10 biased in class C rises is higher than the voltage level of the second input signal RF2b at the time when the output current of the carrier amplifier 20 biased in class AB rises. For example, the output current I_{CSP} of the carrier amplifier 20 biased in class AB rises at the point in time when the input voltage is 0, and the output current I_{BA} Of the peak amplifier 10 biased in class C rises at the point in time when the input voltage is 0.5.

The carrier amplifier 20 is designed to be saturated at the input voltage at which the output current I_{BA} of the peak amplifier 10 rises. Therefore, the output current I_{CSP} increases substantially linearly with respect to the input voltage when the input voltage is within a range from equal to or more than 0 and less than or equal to 0.5. When the input voltage is within a range from equal to or more than 0.5 and less than or equal to 1, the output current I_{CSP} is substantially constant.

Since the output current of the peak amplifier 10 rises after the output current I_{CSP} of the carrier amplifier 20 is saturated, the linearity of the output current of the entire high frequency power amplifier can be maintained.

FIG. 3B is a graph indicating relationships between an input voltage and output voltages of the peak amplifier 10 and the carrier amplifier 20. The horizontal axis represents an input voltage as a normalized value, and the vertical axis represents an output voltage as a normalized value. Here, the normalized value of the maximum value of the output voltage V_{BA} of the peak amplifier 10 is defined as 1. In the graph indicated in FIG. 3B, a solid line represents the output voltage V_{BA} of the peak amplifier 10, and a broken line represents the output voltage V_{CSP} of the carrier amplifier 20. Hereinafter, the normalized value of an output voltage may be simply referred to as an “output voltage”.

The output voltage V_{BA} of the peak amplifier 10 increases linearly with respect to the input voltage when the input voltage is within the range from equal to or more than 0 and less than or equal to 0.5 and increases linearly with respect to the input voltage when the input voltage is within the range from equal to or more than 0.5 and less than or equal to 1. The slope of the output voltage V_{BA} when the input voltage is within the range from equal to or more than 0.5 and less than or equal to 1 is gentler than the slope of the output voltage V_{BA} when the input voltage is within the range from equal to or more than 0 and less than or equal to 0.5.

The output voltage V_{CSP} of the carrier amplifier 20 increases linearly when the input voltage is within the range from equal to or more than 0 and less than or equal to 0.5 and is constant when the input voltage is within the range from equal to or more than 0.5 and less than or equal to 1.

FIG. 3C is a graph indicating relationships between an input voltage and resistance components of load impedances of the peak amplifier 10 and the carrier amplifier 20. The horizontal axis represents an input voltage as a normalized value, and the vertical axis represents a resistance component of a load impedance as a normalized value. The normalized value of a load impedance that is equal to the characteristic impedance Z₀ of the hybrid coupler 30 is defined as 1. In the graph of FIG. 3C, a solid line represents a resistance component of the load impedance Z_{BA} of the peak amplifier 10, and a broken line represents a resistance component of the load impedance Z_{CSP} of the carrier amplifier 20.

The load impedance Z_{CSP} of the carrier amplifier 20 is constant, as indicated by Equation (3), and the normalized value of the load impedance Z_{CSP} is 1. The load impedance Z_{BA} of the peak amplifier 10 is expressed by Equation (2). The load impedance Z_{BA} becomes infinite when the input voltage is 0.5 and decreases as the input voltage increases when the input voltage is within the range from equal to or more than 0.5 and less than or equal to 1.

FIG. 3D is a graph indicating a relationship between an input power and a power-added efficiency. The horizontal axis represents the ratio of an input power to the maximum value of the input power (input power ratio) using a unit [dB], and the vertical axis represents a power-added efficiency using a unit [%].

As with conventional Doherty amplifiers, it is clear that a high efficiency can be achieved in a power backoff region in which the input power ratio is approximately −6 dB.

Next, excellent effects achieved in the first embodiment will be explained. In a conventional sequential LMBA (Pang (2020)), the carrier amplifier 20 is not configured to be a balanced amplifier. When leakage of a high frequency signal from the peak amplifier 10 to the carrier amplifier 20 occurs, the load impedance of the carrier amplifier 20 varies complexly. In particular, in a peak amplifier biased in class C, the load impedance decreases rapidly with respect to an increase of the level of an input signal. Therefore, the load impedance of the carrier amplifier varies depending on frequency around the time when the output power of the carrier amplifier reaches a saturation level. Since such variations depend on frequency, it is difficult to achieve excellent frequency characteristics.

In the first embodiment, since the carrier amplifier 20 is configured to be a balanced amplifier, variations in the characteristics of the carrier amplifier 20 caused by leakage of a high frequency signal from the peak amplifier 10 to the carrier amplifier 20 can be suppressed. Therefore, wideband characteristics can be achieved easily.

Furthermore, as described above with reference to FIG. 3A, since the output current of the peak amplifier 10 rises after the output current of the carrier amplifier 20 is saturated, the linearity of the output current of the entire high frequency power amplifier can be maintained. Furthermore, as described above with reference to FIG. 3D, a high efficiency can be achieved in the backoff region.

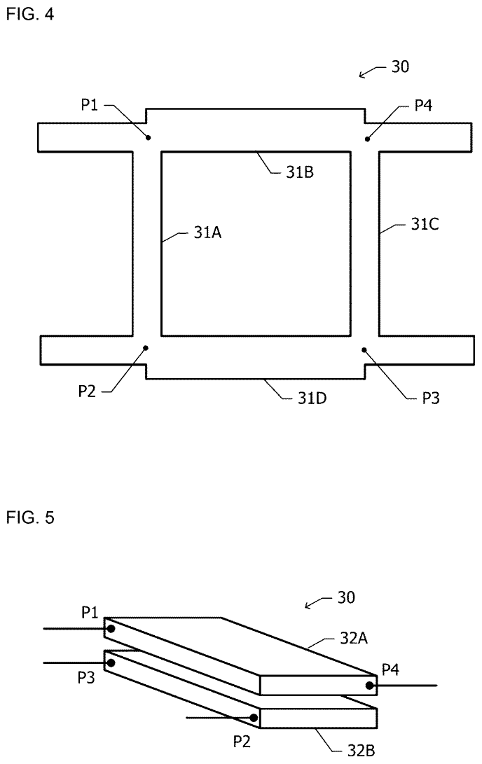

Next, a high frequency power amplifier according to a modification of the first embodiment will be described with reference to FIGS. 4, 5, and 6. In the first embodiment, a 3 dB coupler including a coupled transmission line is used as the hybrid coupler 30. In the modification described below, another type of coupler is used as the hybrid coupler 30.

FIG. 4 is a schematic plan view of the hybrid coupler 30 used in the high frequency power amplifier according to the modification of the first embodiment. In this modification, a branch-line coupler is used as the hybrid coupler 30.

The hybrid coupler 30 includes four transmission lines 31A, 31B, 31C, and 31D each with a length corresponding to ¼ wavelength arranged along the perimeter of a square. For example, the transmission lines 31A, 31B, 31C, and 31D are arranged clockwise in this order. The characteristic impedances of the transmission lines 31A and 31C are represented by Z₀, and the characteristic impedances of the transmission lines 31B and 31D are represented by Z₀/2^{1/2}.

A connection point between the transmission lines 31A and 31B corresponds to the first port P1, a connection point between the transmission lines 31A and 31D corresponds to the second port P2, a connection point between the transmission lines 31C and 31D corresponds to the third port P3, and a connection point between the transmission lines 31B and 31C corresponds to the fourth port P4.

FIG. 5 is a schematic perspective view of the hybrid coupler 30 used in a high frequency power amplifier according to another modification of the first embodiment. In this modification, a parallel-plate coupler is used as the hybrid coupler 30.

The hybrid coupler 30 includes rectangular conductive plates 32A and 32B that face each other in parallel. A corner part of the plate 32A corresponds to the first port P1, and a corner part that is diagonally opposite the corner part corresponding to the first port P1 corresponds to the fourth port P4. A corner part of the plate 32B that overlaps the corner part corresponding to the first port P1 corresponds to the third port P3, and a corner part that is opposite the corner part corresponding to the third port P3 in a long-side direction corresponds to the second port P2.

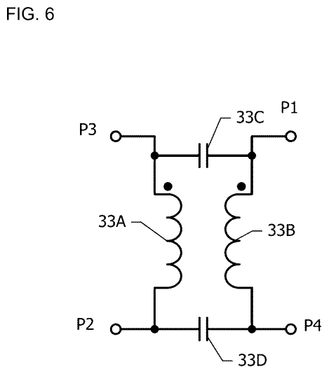

FIG. 6 is an equivalent circuit diagram of the hybrid coupler 30 used in a high frequency power amplifier according to still another modification of the first embodiment. In this modification, a lumped-constant coupler is used as the hybrid coupler 30.

The hybrid coupler 30 includes a pair of inductors 33A and 33B that are magnetically coupled to each other and a pair of capacitors 33C and 33D that are magnetically coupled to each other. One end of the inductor 33A corresponds to the third port P3, and the other end of the inductor 33A corresponds to the second port P2. An end portion of the inductor 33B that is near the third port P3 corresponds to the first port P1, and the opposite end portion of the inductor 33B corresponds to the fourth port P4. The capacitor 33C is connected between the first port P1 and the third port P3, and the capacitor 33D is connected between the second port P2 and the fourth port P4.

As illustrated in FIGS. 4, 5, and 6, a branch-line coupler, a parallel-plate coupler, a lumped-constant coupler, or the like may be used as the hybrid coupler 30.

### Second Embodiment

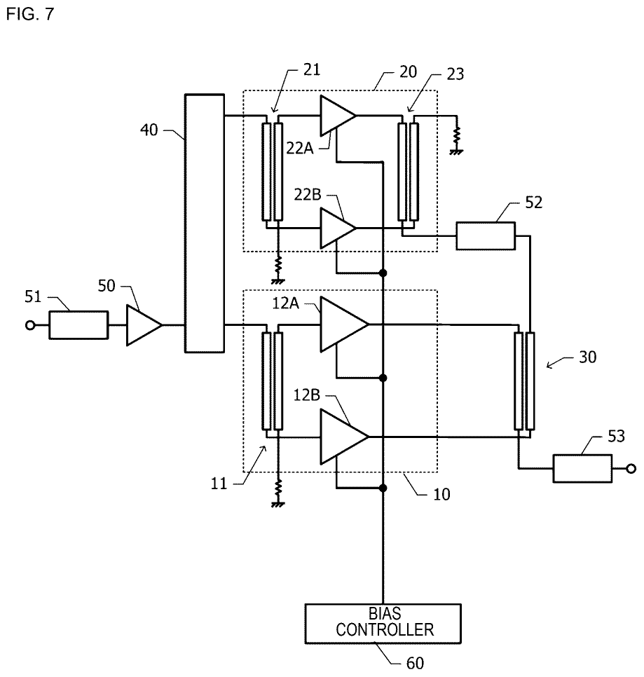

Next, a high frequency power amplifier according to a second embodiment will be described with reference to FIGS. 7 to 10. Description of configurations that are the same as or similar to those of the high frequency power amplifier according to the first embodiment described above with reference to FIGS. 1 to 3D will be omitted below.

FIG. 7 is a block diagram of the high frequency power amplifier according to the second embodiment. In the first embodiment (FIG. 1), a class-C bias is applied to the peak amplifier 10, and a class-AB bias is applied to the carrier amplifier 20. In contrast, in the second embodiment, a bias controller 60 has a plurality of control modes and performs bias control such that biases of the peak amplifier 10 and the carrier amplifier 20 are made different among control modes. The bias controller 60 performs bias control in one control mode selected from among, for example, a very low power mode, a first low power mode, and a second low power mode. These control modes are selected in accordance with a command (instruction) from a user.

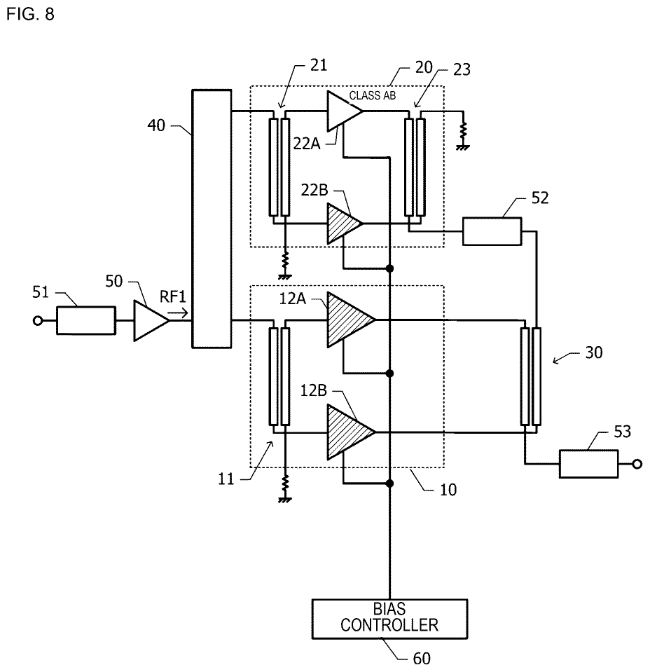

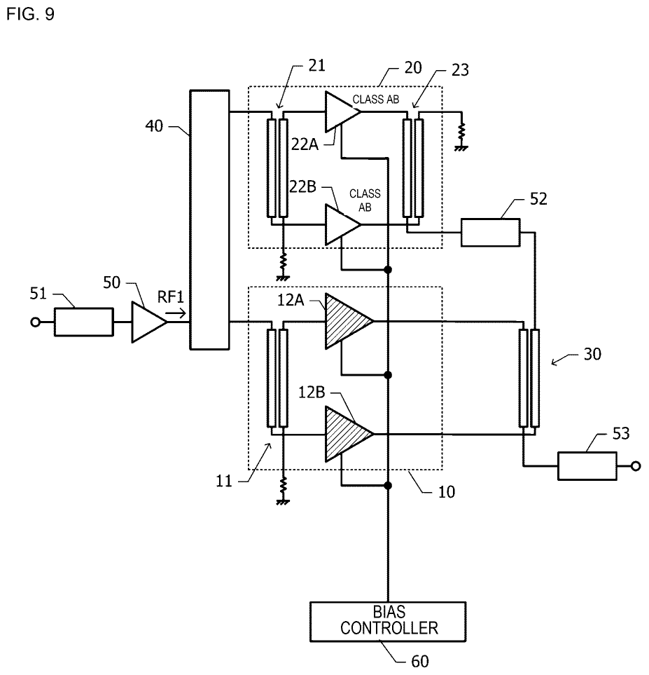

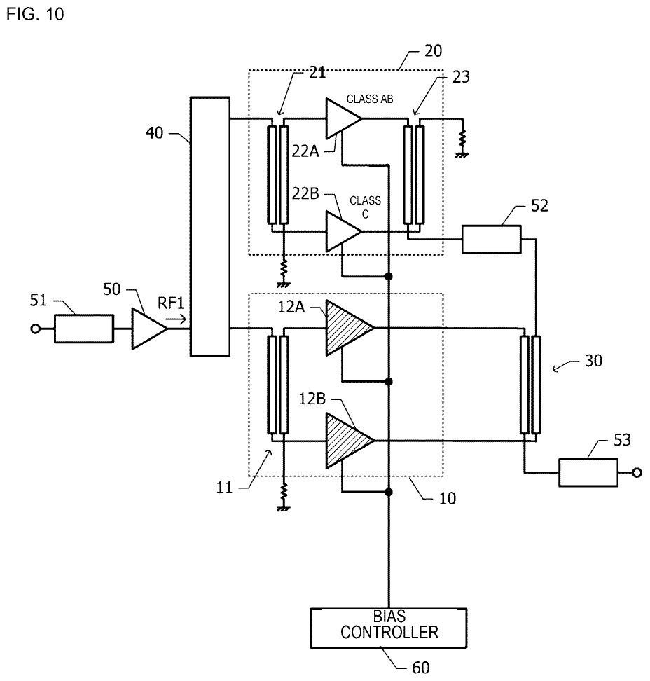

FIG. 8 is a block diagram illustrating a bias control state at the time when the bias controller 60 performs bias control in the very low power mode. When the control mode is the very low power mode, the bias controller 60 applies a class-AB bias to the second amplifier 22A of the carrier amplifier 20 but does not apply any bias to the second amplifier 22B of the carrier amplifier 20. That is, the second amplifier 22B enters a shut-down state and does not perform an amplifying operation. Furthermore, no bias is applied to the first amplifier 12A or the first amplifier 12B of the peak amplifier 10. That is, the peak amplifier 10 enters the shut-down state and does not perform an amplifying operation. In FIG. 8, the amplifiers in the shut-down state are indicated by hatching lines. Also, in FIGS. 9 and 10, which will be described below, amplifiers in the shut-down state are indicated by hatching lines.

FIG. 9 is a block diagram illustrating a bias control state at the time when the bias controller 60 performs bias control in the first low power mode. When the control mode is the first low power mode, the bias controller 60 applies a class-AB bias to the two second amplifiers 22A of the carrier amplifier 20 but does not apply any bias to the first amplifier 12A or the first amplifier 12B of the peak amplifier 10.

FIG. 10 is a block diagram illustrating a bias control state at the time when the bias controller 60 performs bias control in the second low power mode. When the control mode is the second low power mode, the bias controller 60 applies a class-AB bias to the second amplifier 22A of the carrier amplifier 20 and applies a class-C bias to the second amplifier 22B of the carrier amplifier 20. The two second amplifiers 22A and 22B operate as Doherty amplifiers. No bias is applied to the first amplifier 12A or the first amplifier 12B of the peak amplifier 10.

Next, excellent effects achieved in the second embodiment will be described. In the second embodiment, since some amplifiers enter the shut-down state according to control modes, the idle current is reduced as a whole, and the power-added efficiency can thus be improved. A control mode to be set can be determined according to the maximum signal level of the first input signal RF1.

When the control mode is the very low power mode, the effect of reducing the idle current becomes maximum. Furthermore, the size of transistors configuring the carrier amplifier 20 is smaller than the size of transistors configuring the peak amplifier 10. When the control mode is the first low power mode or the second low power mode, by shutting down the transistors of the peak amplifier 10 that are large in size, the large effect of reducing the idle current can be achieved.

When the control mode is the second low power mode (FIG. 10), since the carrier amplifier 20 operates as a Doherty power amplifier, a further improvement in the power-added efficiency can be achieved compared to the case in the first low power mode.

### Third Embodiment

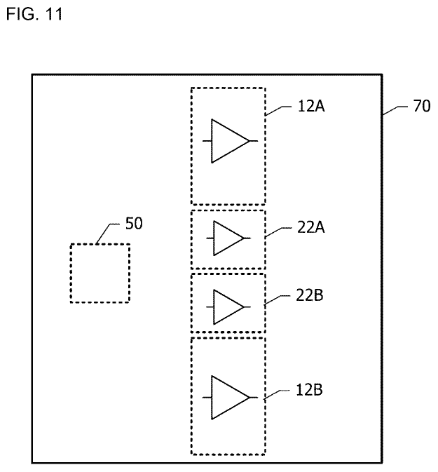

Next, a high frequency power amplifier according to a third embodiment will be described with reference to FIG. 11. Description of configurations that are the same as or similar to those of the high frequency power amplifier according to the first embodiment described above with reference to FIGS. 1 to 3D will be omitted below.

FIG. 11 is a schematic diagram illustrating a positional relationship between the two first amplifiers 12A and 12B of the peak amplifier 10, the two second amplifiers 22A and 22B of the carrier amplifier 20, and the drive-stage amplifier 50 in the high frequency power amplifier according to the third embodiment. In the first embodiment, the positional relationship between these components is not particularly limited.

In the third embodiment, the two first amplifiers 12A and 12B of the peak amplifier 10, the two second amplifiers 22A and 22B of the carrier amplifier 20, and the drive-stage amplifier 50 are formed at a common substrate 70. The two second amplifiers 22A and 22B of the carrier amplifier 20 are arranged at positions sandwiched between the two first amplifiers 12A and 12B of the peak amplifier 10 when the substrate 70 is seen in a plan view. More specifically, the first amplifier 12A, the second amplifier 22A, the second amplifier 22B, and the first amplifier 12B are arranged in a line in this order. The arrangement order of the second amplifier 22A and the second amplifier 22B may be changed.

The drive-stage amplifier 50 is arranged at a position distant in a direction intersecting the line in which the first amplifiers 12A and 12B and the second amplifiers 22A and 22B are arranged.

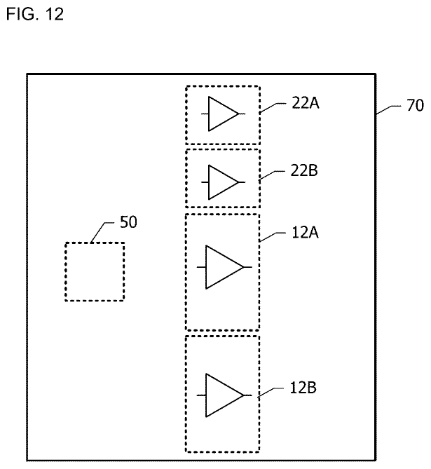

Next, excellent effects achieved in the third embodiment will be described while comparing them with a comparative example illustrated in FIG. 12.

FIG. 12 is a schematic diagram illustrating a positional relationship between the two first amplifiers 12A and 12B of the peak amplifier 10, the two second amplifiers 22A and 22B of the carrier amplifier 20, and the drive-stage amplifier 50 in a high frequency power amplifier according to a comparative example. In this comparative example, the second amplifiers 22A and 22B of the carrier amplifier 20 and the first amplifiers 12A and 12B of the peak amplifier 10 are arranged in a line in this order.

When attention is paid to the first amplifier 12A of the peak amplifier 10, the first amplifier 12B and the second amplifier 22B are arranged on both sides of the first amplifier 12A. When attention is paid to the first amplifier 12B, the first amplifier 12A is arranged on only one side of the first amplifier 12B. Therefore, when heat is generated at the first amplifiers 12A and 12B and the second amplifiers 22A and 22B during an operation of the high frequency power amplifier, a difference in thermal impact occurs between the two first amplifiers 12A and 12B. Similarly, a difference in thermal impact occurs also between the two second amplifiers 22A and 22B of the carrier amplifier 20. Such differences in thermal impact cause a malfunction of the high frequency power amplifier.

In the third embodiment, when attention is paid to each of the two first amplifiers 12A and 12B of the peak amplifier 10, the second amplifier 22A or 22B is arranged on only one side of each of the first amplifiers 12A and 12B. Furthermore, when attention is paid to the second amplifier 22A of the carrier amplifier 20, the first amplifier 12A is arranged on one side of the second amplifier 22A and the second amplifier 22B is arranged on the other side of the second amplifier 22A. When attention is paid to the second amplifier 22B, the first amplifier 12B is arranged on one side of the second amplifier 22B and the second amplifier 22A is arranged on the other side of the second amplifier 22B.

Therefore, thermal impacts on the first amplifiers 12A and 12B of the peak amplifier 10 are substantially equal to each other, and thermal impacts on the two second amplifiers 22A and 22B of the carrier amplifier 20 are substantially equal to each other. A difference in thermal impact is less likely to occur between the first amplifiers 12A and 12B of the peak amplifier 10, and a difference in thermal impact is also less likely to occur between the two second amplifiers 22A and 22B of the carrier amplifier 20. Therefore, a malfunction of the high frequency power amplifier caused by a difference in thermal impact is less likely to occur.

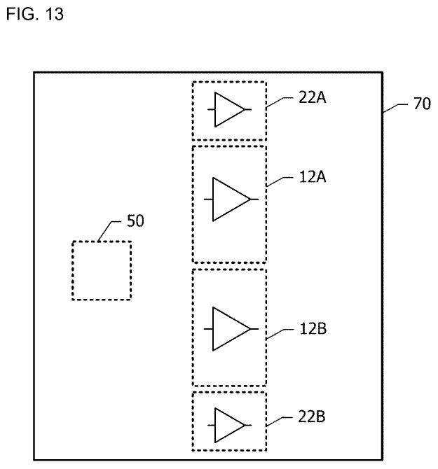

Next, a high frequency power amplifier according to a modification of the third embodiment will be described with reference to FIG. 13. FIG. 13 is a schematic diagram illustrating a positional relationship between the two first amplifiers 12A and 12B of the peak amplifier 10, the two second amplifiers 22A and 22B of the carrier amplifier 20, and the drive-stage amplifier 50 in the high frequency power amplifier according to the modification of the third embodiment.

In the third embodiment (FIG. 11), the two second amplifiers 22A and 22B of the carrier amplifier 20 are arranged at positions sandwiched between the two first amplifiers 12A and 12B of the peak amplifier 10 when the substrate 70 is seen in a plan view. In contrast, in this modification, the positional relationship between the peak amplifier 10 and the carrier amplifier 20 is changed. That is, the two first amplifiers 12A and 12B of the peak amplifier 10 are arranged at positions sandwiched between the two second amplifiers 22A and 22B of the carrier amplifier 20.

Also in the modification illustrated in FIG. 13, a malfunction of the high frequency power amplifier caused by a difference in thermal impact is less likely to occur, as in the third embodiment (FIG. 11).

### Fourth Embodiment

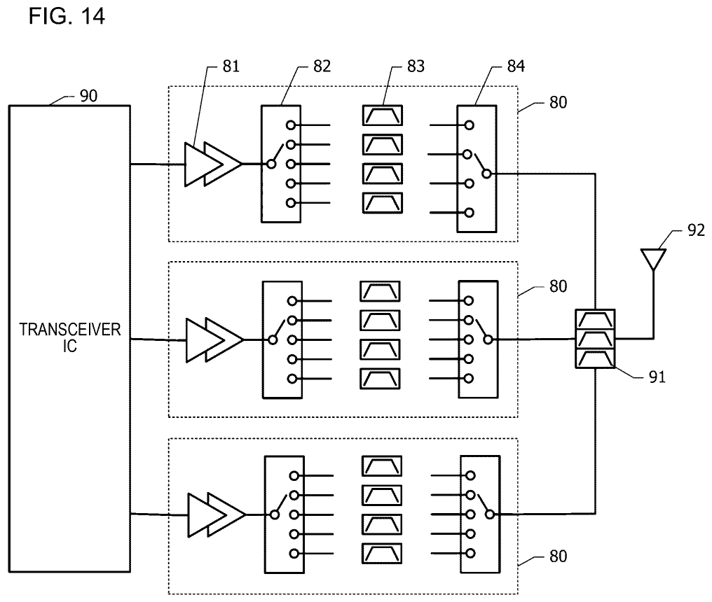

Next, a communication apparatus according to a fourth embodiment will be described with reference to FIG. 14. FIG. 14 is a block diagram of the communication apparatus according to the fourth embodiment. The communication apparatus according to the fourth embodiment includes a transceiver IC 90, a plurality of transmission systems 80, a multiplexer 91, and an antenna 92. The plurality of transmission systems 80 each include a high frequency power amplifier 81, a first switch 82, a plurality of filter circuits 83, and a second switch 84. As the high frequency power amplifier 81, the high frequency power amplifier according to the first embodiment, the second embodiment, or the third embodiment is used.

A high frequency signal to be transmitted is inputted to each of the high frequency power amplifiers 81 of the plurality of transmission systems 80 from the transceiver IC 90. The high frequency signal amplified by the high frequency power amplifier 81 is inputted to a filter circuit 83 selected by the first switch 82. The high frequency signal that has passed through the filter circuit 83 travels through the second switch 84 and the multiplexer 91 and is transmitted to the antenna 92.

Next, excellent effects achieved in the fourth embodiment will be described. In the fourth embodiment, since the high frequency power amplifier according to the first embodiment, the second embodiment, or the third embodiment is used as the high frequency power amplifier 81, linearity of input/output characteristics can be maintained, and a high efficiency can be achieved in a backoff region. Furthermore, wideband characteristics can be achieved easily.

Each of the embodiments described above is illustrative and, obviously, components illustrated in different embodiments can be partially replaced or combined. Similar operational effects obtained by similar configurations in multiple embodiments are not repeatedly described in each embodiment. Furthermore, the present disclosure is not intended to be limited to the embodiments described above. For example, various changes, improvements, combinations, and so on may be apparent to those skilled in the art.

The disclosure will be disclosed below based on foregoing embodiments described herein.

<1> A high frequency power amplifier including: a hybrid coupler including a first port, a second port, a third port, and a fourth port; an input signal splitter that splits a first input signal at a high frequency into two second input signals; a peak amplifier including two first amplifiers that amplify two high frequency signals obtained by splitting a first one of the second input signals, output ends of the two first amplifiers being coupled to the first port and the second port; and a carrier amplifier including two second amplifiers that amplify two high frequency signals obtained by splitting a second one of the second input signals and a combiner that combines the high frequency signals amplified by the two second amplifiers together and inputs a combined high frequency signal to the third port, wherein a voltage level of the first input signal at a time when an output current of the peak amplifier rises is higher than a voltage level of the first input signal at a time when an output current of the carrier amplifier rises, and wherein the hybrid coupler has a configuration in which the high frequency signals inputted to the first port and the second port are combined together and outputted from the fourth port and load impedances of the two first amplifiers of the peak amplifier vary according to a current level of the high frequency signal inputted to the third port from the carrier amplifier.

<2> The high frequency power amplifier according to <1>, wherein in a case where the voltage level of the first input signal is increased, at the time when the output current of the peak amplifier rises, the output current of the carrier amplifier is saturated.

<3> The high frequency power amplifier according to <1> or <2>, further including: a bias controller that controls biases of the carrier amplifier and the peak amplifier, wherein the bias controller has a plurality of control modes, each of the control modes having different biases of the carrier amplifier and the peak amplifier.

<4> The high frequency power amplifier according to <3>, wherein in one of the plurality of control modes, the bias controller causes the two second amplifiers of the carrier amplifier to operate as Doherty amplifiers.

<5> The high frequency power amplifier according to <3> or <4>, wherein in one of the plurality of control modes, the bias controller applies to the two first amplifiers of the peak amplifier a bias that does not generate an output current regardless of the voltage level of the first input signal.

<6> The high frequency power amplifier according to any one of <3> to <5>, wherein in one of the plurality of control modes, the bias controller applies to a first one of the two second amplifiers of the carrier amplifier a bias that does not generate an output current regardless of the voltage level of the first input signal and applies to a second one of the two second amplifiers a class-AB bias or a class-B bias.

<7> The high frequency power amplifier according to any one of <1> to <6>, wherein the two first amplifiers of the peak amplifier and the two second amplifiers of the carrier amplifier are formed at a common substrate, and wherein the two first amplifiers and the two second amplifiers are arranged such that the two first amplifiers are sandwiched between the two second amplifiers or the two second amplifiers are sandwiched between the two first amplifiers.

What is claimed is:

1. A high frequency power amplifier comprising:
a hybrid coupler having a first port, a second port, a third port, and a fourth port;
an input signal splitter configured to split a first input signal at a high frequency into two second input signals;
a peak amplifier comprising two first amplifiers configured to amplify two high frequency signals obtained by splitting a first one of the second input signals, output ends of the two first amplifiers being coupled to the first port and the second port, respectively; and
a carrier amplifier comprising two second amplifiers configured to amplify two high frequency signals obtained by splitting a second one of the second input signals, and a combiner configured to combine the high frequency signals amplified by the two second amplifiers together and to output a combined high frequency signal to the third port,
wherein a voltage level of the first input signal at a time when an output current of the peak amplifier rises is greater than a voltage level of the first input signal at a time when an output current of the carrier amplifier rises,
wherein the high frequency signals input to the first port and the second port are combined together and output from the fourth port, and
wherein load impedances of the two first amplifiers of the peak amplifier vary according to a current level of the high frequency signal input to the third port from the carrier amplifier.

2. The high frequency power amplifier according to claim 1, wherein in a case where the voltage level of the first input signal is increased, at the time when the output current of the peak amplifier rises, the output current of the carrier amplifier is saturated.

3. The high frequency power amplifier according to claim 1, further comprising:
a bias controller configured to control biases of the carrier amplifier and the peak amplifier,
wherein the bias controller has a plurality of control modes, each of the control modes corresponding to different biases of the carrier amplifier and the peak amplifier.

4. The high frequency power amplifier according to claim 2, further comprising:
a bias controller configured to control biases of the carrier amplifier and the peak amplifier,
wherein the bias controller has a plurality of control modes, each of the control modes corresponding to different biases of the carrier amplifier and the peak amplifier.

5. The high frequency power amplifier according to claim 3, wherein in one of the plurality of control modes, the bias controller is configured to cause the two second amplifiers of the carrier amplifier to operate as Doherty amplifiers.

6. The high frequency power amplifier according to claim 3, wherein in one of the plurality of control modes, the bias controller is configured to apply, to the two first amplifiers of the peak amplifier, a bias that does not generate an output current regardless of the voltage level of the first input signal.

7. The high frequency power amplifier according to claim 3, wherein in one of the plurality of control modes, the bias controller is configured to:
apply, to a first one of the two second amplifiers of the carrier amplifier, a bias that does not generate an output current regardless of the voltage level of the first input signal; and
apply, to a second one of the two second amplifiers, a class-AB bias or a class-B bias.

8. The high frequency power amplifier according to claim 1,
wherein the two first amplifiers of the peak amplifier and the two second amplifiers of the carrier amplifier are on a common substrate, and
wherein the two first amplifiers are sandwiched between the two second amplifiers, or the two second amplifiers are sandwiched between the two first amplifiers.

9. The high frequency power amplifier according to claim 2,
wherein the two first amplifiers of the peak amplifier and the two second amplifiers of the carrier amplifier are on a common substrate, and
wherein the two first amplifiers are sandwiched between the two second amplifiers, or the two second amplifiers are sandwiched between the two first amplifiers.
